(19) United States
(12) Patent Application Publication
(10) Pub. No.: US 2026/0079191 A1
(43) Pub. Date: Mar. 19, 2026

(54) SEMICONDUCTOR DEVICE, POWER SUPPLY DEVICE AND VEHICLE

(71) Applicant: ROHM Co., Ltd., Kyoto (JP)

(72) Inventor: Yuki Teramae, Kyoto (JP)

(73) Assignee: ROHM Co., Ltd., Kyoto (JP)

(21) Appl. No.: 19/319,694

(22) Filed: Sep. 4, 2025

(30) Foreign Application Priority Data
Sep. 13, 2024 (JP) 2024-159195

(51) Int. Cl. G01R 31/00; G07C 5/00; G07C 5/08

(52) U.S. Cl. CPC G01R 31/007; G07C 5/008; G07C 5/0808; G07C 5/0816

(57) ABSTRACT

To ensure the safety of a machine in which a semiconductor device is provided. In a semiconductor device (10), a diagnostic circuit (113) is able to perform in-operation diagnosis (ABIST on-demand) that operates an error detection part (11P, 11D) in a state in which an analog circuit (131, 132) operates, and the semiconductor device is configured to have a mask circuit (114) that masks inputting of an error detection signal (SEP, SED) to a determination circuit (111, 112) when the in-operation diagnosis (ABIST on-demand) is performed.

### CROSS-REFERENCE TO RELATED APPLICATION

This application claims the priority benefit of Japanese application serial no. 2024-159195, filed on Sep. 13, 2024. The entirety of the above-mentioned patent application is hereby incorporated by reference herein and made a part of this specification.

### BACKGROUND

### Technical Field

The disclosure relates to a semiconductor device, a power supply device and a vehicle.

### Description of Related Art

In recent years, a configuration having a self-diagnostic function referred to as built-In self test (BIST), which confirms that the device is operating normally, has been adopted in automotive integrated circuits (ICs) (see, for example, Japanese Patent Application Laid-open No. 2023-52304).

There is a demand to ensure the safety of the machine in which semiconductor devices such as automotive ICs are mounted.

### SUMMARY

A semiconductor device according to an aspect of the disclosure includes: an analog circuit; an analog circuit; a control circuit, configured to control the analog circuit; an error detection part, disposed in the control circuit and configured to detect an error of a signal or a voltage and output an error detection signal; a determination circuit, configured to determine whether the error occurs based on the error detection signal; and a diagnostic circuit, configured to diagnose whether the error detection part is good based on the error detection signal. The diagnostic circuit is able to perform in-operation diagnosis in which the error detection part is operated, in a state in which the analog circuit operates. The semiconductor device is configured to have a mask circuit that masks inputting of the error detection signal to the determination circuit when the in-operation diagnosis is performed.

### BRIEF DESCRIPTION OF THE DRAWINGS

FIG. 1 is a diagram showing the overall configuration of a power supply device using a semiconductor device.

FIG. 2 is a diagram showing a detailed configuration of the semiconductor device.

FIG. 3 is a diagram showing an ASIL.

FIG. 4 is a diagram showing the state of each signal when there is no malfunction in a protection element and a detection element in ABIST on-demand.

FIG. 5 is a diagram showing the state of each signal when the detection element malfunctions.

FIG. 6 is a diagram showing the state of each signal when the protection element malfunctions.

FIG. 7 is a diagram showing the state of each signal when the detection element and protection element malfunction.

FIG. 8 is a flowchart showing processes of ABIST on-demand.

FIG. 9 is a diagram showing the configuration of a power supply device according to a modified example.

FIG. 10 is a diagram showing the configuration of an example of a vehicle including the power supply device.

### DESCRIPTION OF THE EMBODIMENTS

In the specification, a metal oxide semiconductor (MOS) field effect transistor refers to a transistor whose gate structure includes at least three layers, i.e., “a layer made of a conductive material or a semiconductor such as polysilicon with a small resistance value”, “an insulation layer”, and “a P-channel type, N-channel type, or intrinsic semiconductor layer.” That is, the gate structure of the MOS field effect transistor is not limited to a three-layer structure of metal, oxide, and semiconductor. Also, a MOS field effect transistor may be simply referred to as a MOS transistor. In addition, a P-channel type MOS transistor is described as a PMOS transistor, and an N-channel type MOS transistor is described as an NMOS transistor.

“Connection” between multiple parts forming a circuit, such as any element, line, etc., includes the case of mechanical connection as well as electrical connection, i.e., a state where electricity flows. That is, “to connect” includes cases of “to electrically connect.”

### Power Supply Device 100

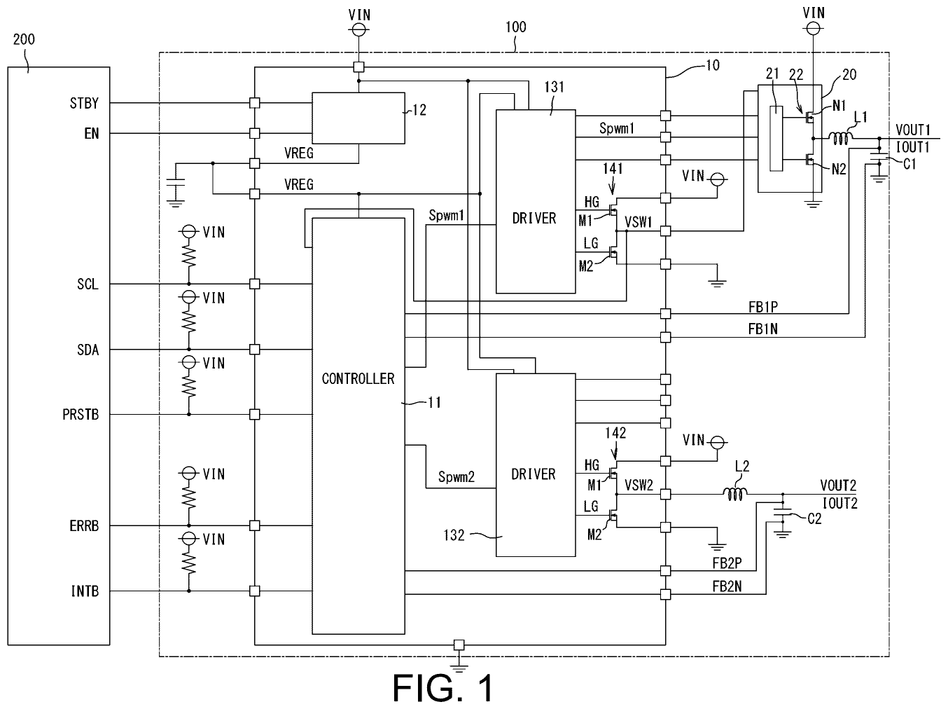

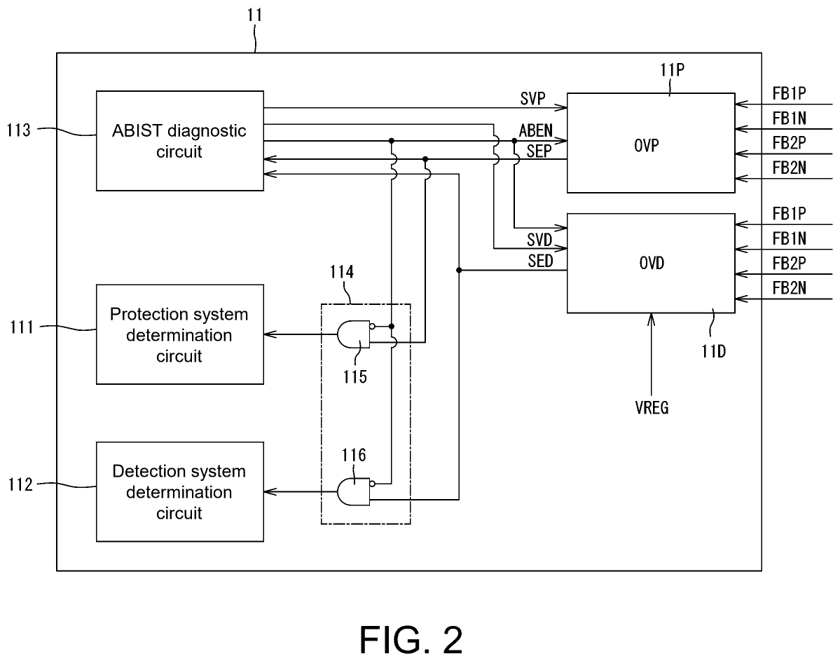

FIG. 1 is a diagram showing the overall configuration of a power supply device 100 using a semiconductor device 10. FIG. 2 is a diagram showing a detailed configuration of the semiconductor device 10. In the semiconductor device 10 shown in FIG. 2, the connection between a control circuit 11 and a driver circuit 131 is shown, but the driver circuit 132 has the same connection configuration as the driver circuit 131.

The power supply device 100 is a switching power supply device. The power supply device 100 is configured to be controlled based on instructions from a motor control unit (MCU) 200. The power supply device 100 is used, for example, as a power supply for a vehicle.

As shown in FIG. 1, the MCU 200 is connected to the semiconductor device 10 of the power supply device 100, which will be described later. The semiconductor device 10 receives a standby signal STBY, an enable signal EN, a clock signal SCL, a data signal SDA, and a reset signal PRSTB from the MCU 200. The standby signal STBY, the enable signal EN, the clock signal SCL, the data signal SDA, and the reset signal PRSTB are supplied to each circuit of the semiconductor device 10 through each external terminal provided in the semiconductor device 10 of the power supply device 100.

Also, from the semiconductor device 10 to the MCU 200, an error signal ERRB, an interrupt signal INTB, and a data signal SDA are output through each external terminal of the semiconductor device 10. The data signal SDA is data that is transmitted and received over a bidirectional communication line between the MCU 200 and the semiconductor device 10 by using an inter integrated circuit (I2C). Other signals may also be configured to be transmitted by using the same I2C.

As shown in FIG. 1, the power supply device 100 is a power supply large scale integration (LSI) capable of outputting an output voltage and an output current from multiple channels. The power supply device 100 shown in FIG. 1 has 2 channels. The power supply device 100 has a configuration that integrates the semiconductor device 10, an output part 20 to be described later, and a rectification smoothing circuit to be described later in one package. The output part 20 may be configured to be connected external to the power supply LSI. Similarly, the rectification smoothing circuit may be configured to be connected external to the power supply LSI.

Also, the power supply device 100 is an analog circuit that operates by using an analog signal. The power supply device 100 includes the semiconductor device 10 and the output part 20. In the power supply device 100 shown in FIG. 1, the first channel is configured to output an output voltage VOUT1 from the output part 20 provided outside the semiconductor device 10, and the second channel is configured to output an output voltage VOUT2 from a bridge circuit 142, which will be described later, provided inside the semiconductor device 10.

### Semiconductor Device 10

The semiconductor device 10 is a power management integrated circuit (PMIC) that controls the power supply device 100. As shown in FIG. 1, the semiconductor device 10 includes a control circuit 11, an internal voltage generation circuit 12, driver circuits 131, 132, and bridge circuits 141, 142. The semiconductor device 10 also includes components other than the above, and has a configuration in which multiple components are integrated into one package.

### Internal Voltage Generation Circuit 12

The internal voltage generation circuit 12 is a circuit that generates and outputs an internal voltage VREG based on an input voltage VIN, and is configured, for example, by using a low drop-out (LDO). The standby signal STBY and the enable signal EN are input to the internal voltage generation circuit 12. When either the standby signal STBY or the enable signal EN rises to the high level, the internal voltage generation circuit 12 generates the internal voltage VREG. The internal voltage generation circuit 12 is connected to an output capacitor provided externally. The internal voltage VREG is supplied to the output capacitor. Subsequently, the internal voltage VREG based on the charge stored in the output capacitor is internally input back and supplied to the control circuit 11 and the driver circuits 131, 132. Accordingly, the operations of the control circuit 11 and the driver circuits 131, 132 are initiated.

### Bridge Circuits 141, 142

The bridge circuit 141 and the bridge circuit 142 are both configurations included in the semiconductor device 10. The bridge circuit 141 and the bridge circuit 142 have substantially same configuration. Therefore, the detailed configuration will be described with reference to the bridge circuit 141, and the detailed description of the same parts in the bridge circuit 142 as in the bridge circuit 141 will be omitted.

As shown in FIG. 1, the bridge circuit 141 includes a high-side switching element M1 and a low-side switching element M2. The high-side switching element M1 and the low-side switching element M2 are connected in series. The high-side switching element M1 and the low-side switching element M2 are NMOS transistors. The drain of the high-side switching element M1 is connected to the application terminal of the input voltage VIN. That is, the input voltage VIN is supplied to the drain of the high-side switching element M1. Also, the source of the low-side switching element M2 is connected to the application terminal of the ground voltage.

The gate of the high-side switching element M1 is connected to the driver circuit 131, and a high-side drive signal HG is supplied. Also, the gate of the low-side switching element M2 is connected to the driver circuit 131, and a low-side drive signal LG is supplied.

In the bridge circuit 141, the high-side switching element M1 and the low-side switching element M2 are controlled to be either both in the OFF state or one in the ON state and the other in the OFF state. The high-side switching element M1 and the low-side switching element M2 are controlled so that the high-side switching element M1 and the low-side switching element M2 are not both in the ON state simultaneously.

In the bridge circuit 141, the high-side switching element M1 is an NMOS transistor, but the high-side switching element M1 may also be a PMOS transistor.

A switch voltage VSW1 is generated at the connection point between the source of the high-side switching element M1 and the drain of the low-side switching element M2. The switch voltage VSW1 is output externally.

In the case of outputting the output voltage and the output current to a load by using the bridge circuit 141, an output voltage VOUT1 corresponding to the switch voltage VSW1 is output. Also, in the case where the output part 20 is connected and the output voltage and the output current are output from the output part 20, the switch voltage VSW1 is supplied to the output part 20 as a sense voltage.

The bridge circuit 142, similar to the bridge circuit 141, includes the high-side switching element M1 and the low-side switching element M2. In addition, the drain of the high-side switching element M1 is connected to the application terminal of the input voltage VIN. Also, the source of the low-side switching element M2 is connected to the application terminal of the ground voltage.

The gate of the high-side switching element M1 of the bridge circuit 142 is connected to the driver circuit 132, and the high-side drive signal HG is supplied. Also, the gate of the low-side switching element M2 is connected to the driver circuit 132, and a low-side drive signal LG is supplied.

In the bridge circuit 142, a switch voltage VSW2 is generated at the connection point between the source of the high-side switching element M1 and the drain of the low-side switching element M2. The switch voltage VSW2 is output externally.

### Output Part 20

The output part 20 has a configuration in which the drive part 21 and the bridge circuit 22 are integrated in a single package. Also, the bridge circuit 22 of the output part 20 includes a high-side switching element N1 and a low-side switching element N2. The high-side switching element N1 and the low-side switching element N2 have substantially the same configuration as the high-side switching element M1 and the low-side switching element M2 of the bridge circuits 141, 142.

The drive part 21 has substantially the same configuration as the portions of the driver circuits 131, 132 that drive the bridge circuits 141, 142. That is, a drive signal Spwm1 is supplied to the drive part 21. Based on the drive signal Spwm1, the drive part 21 generates a high-side drive signal HG supplied to the gate of the high-side switching element N1, and also generates a low-side drive signal LG supplied to the gate of the low-side switching element N2.

The first terminal of an inductor L1 is connected to the connection point between the high-side switching element N1 and the low-side switching element N2 of the bridge circuit 22 of the output part 20. Also, the second terminal of the inductor L1 is connected to the first terminal of a capacitor C1. Also, the second terminal of the capacitor C1 is connected to the application terminal of the ground voltage. The connection point between the inductor L1 and the capacitor C1 is output externally as the output of the output part 20. That is, in the power supply device 100, the output voltage VOUT1 and an output current IOUT1, which are rectified and smoothed by a rectification smoothing circuit formed by the inductor L1 and the capacitor C1 from the switch voltage at the connection point of the bridge circuit, are output.

In the case of outputting the output voltage VOUT1 and the output current IOUT1 based on the switch voltage VSW1 at the connection point between the high-side switching element M1 and the low-side switching element M2 of the bridge circuit 141, the first terminal of the inductor L1 is connected to the connection point between the high-side switching element M1 and the low-side switching element M2 of the bridge circuit 141. Also, in the power supply device 100, a rectification smoothing circuit formed by the inductor L2 and the capacitor C2 is connected to the connection point between the high-side switching element M1 and the low-side switching element M2 of the bridge circuit 142.

### Driver Circuit 131, Driver Circuit 132

The drive signals Spwm1 and Spwm2 are input from the control circuit 11 to the driver circuits 131, 132. The drive signal Spwm1 is a signal that determines the ON period of the high-side switching element M1 of the bridge circuit 141. Also, the drive signal Spwm2 is a signal that determines the ON period of the high-side switching element M1 of the bridge circuit 142.

Based on the drive signal Spwm1, the driver circuit 131 generates the high-side drive signal HG supplied to the gate of the high-side switching element M1 of the bridge circuit 141, and also generates a low-side drive signal LG supplied to the gate of the low-side switching element M2. Also, based on the drive signal Spwm2, the driver circuit 132 generates the high-side drive signal HG supplied to the gate of the high-side switching element M1 of the bridge circuit 142, and also generates the low-side drive signal LG supplied to the gate of the low-side switching element M2.

Also, the driver circuits 131, 132 are configured to be connectable to the output part 20 that is external, and in such case, the driver circuits 131, 132 are configured to output the drive signals Spwm1, Spwm2 to the output part 20. In the power supply device 100 of the disclosure, the output part 20 is connected to the driver circuit 131.

The driver circuit 131 and the driver circuit 132 have substantially the same configuration. Therefore, in the following description, the driver circuit 131 and the bridge circuit 141 will be specifically described as representatives, and then the portions of the driver circuit 132 differing from the driver circuit 131 will be described.

The driver circuit 131 outputs the high-side drive signal HG to the gate of the high-side switching element M1 of the bridge circuit 141, and outputs the low-side drive signal LG to the gate of the low-side switching element M2.

In the bridge circuit 141, the high-side switching element M1 becomes the ON state when the high-side drive signal HG is at the high level, and the high-side switching element M1 becomes the OFF state when the high-side drive signal HG is at the low level. Similarly, the low-side switching element M2 becomes the ON state when the low-side drive signal LG is at the high level, and the low-side switching element M2 becomes the OFF state when the low-side drive signal LG is at the low level.

The driver circuit 131 outputs the high-side drive signal HG and the low-side drive signal LG, so that both the high-side switching element M1 and the low-side switching element M2 are in the OFF state, or one is in the ON state and the other is in the OFF state. The driver circuit 131 outputs the high-side drive signal HG and the low-side drive signal LG, so that the high-side switching element M1 and the low-side switching element M2 do not both become the ON state simultaneously.

The control circuit 11 is configured to acquire the voltages of both terminals of the capacitor C1 of the rectification smoothing circuit as feedback signals FB1P, FB1N. Based on the feedback signals FB1P, FB1N, the control circuit 11 acquires a voltage corresponding to the output voltage VOUT1, and outputs the drive signal Spwm1 so that the output voltage VOUT1 becomes a determined voltage.

Similarly, the control circuit 11 is configured to acquire the voltages of both terminals of the capacitor C2 of the rectification smoothing circuit as feedback signals FB2P, FB2N. Based on the feedback signals FB2P, FB2N, the control circuit 11 acquires a voltage corresponding to the output voltage VOUT2, and outputs the drive signal Spwm2 so that the output voltage VOUT2 becomes a determined voltage.

### Control Circuit 11

As shown in FIG. 1, the control circuit 11 is a circuit that controls the semiconductor device 10. The control circuit 11 generates the drive signals Spwm1, Spwm2 for driving the respective bridge circuits 141, 142, and outputs the drive signals Spwm1, Spwm2 to the driver circuits 131, 132 disposed inside the semiconductor device 10.

In recent years, there has been an increasing demand for the semiconductor device 10 mounted in vehicles to comply with the ISO26262 standard, which is specified to achieve functional safety of vehicles. In the ISO26262 standard, the risk level of errors occurring in vehicle components is set by dividing the errors into levels referred to as automotive safety integrity levels (ASILs). ASIL includes four levels, i.e., A level (ASIL_A), B level (ASIL_B), C level (ASIL_C), and D level (ASIL_D), which indicate in order the increasing risk level when the error occurs.

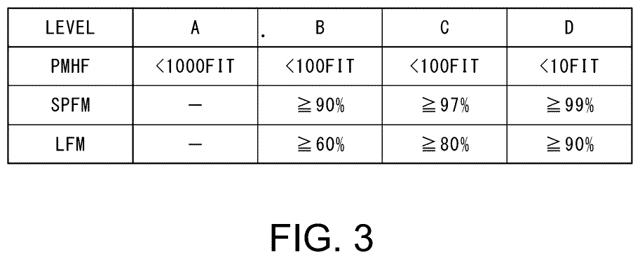

In the ISO26262 standard, for failures occurring in automotive semiconductor devices, evaluation is performed by using the frequency of failure occurrence (failure rate) calculated by statistical methods. FIG. 3 is a diagram showing ASIL.

As shown in FIG. 3, in the ISO26262 standard, for each ASIL level, a target failure rate is set, which represents the time average of the failure probability of an item over the service time of the vehicle (probabilistic metric for random hardware failures (PMHF)). For ASIL_A, the PMHF is 1000 failures in time (FIT): the average number of failures per billion hours). Similarly, for ASIL_B, ASIL_C, and ASIL_D, the PMHF values are 100 FIT, 100 FIT, and 10 FIT, respectively.

Furthermore, it is difficult to completely prevent failures from occurring in components forming a vehicle. Specifically, in many cases, it is difficult to manufacture the semiconductor device 10 to achieve the failure rate of ASIL_D level. On the other hand, in the semiconductor device 10, even if a failure occurs, if that failure can be detected quickly, it may be possible to suppress the occurrence of malfunctions in the vehicle as a whole. Therefore, in the ISO26262 standard, a failure detection rate, which is the probability of detecting failures, is set.

Furthermore, in the ISO26262 standard, the target values for the failure detection rate are set by dividing into two types, i.e., single point failure metrics (SPFM) and latent failure Metrics (LFM), for each ASIL level. SPFM refers to a failure that directly deviates from the safety goal in a single occurrence. Additionally, LFM refers to a failure that deviates from the safety goal due to a latent malfunction.

In the semiconductor device 10, to detect the failures described above, for example, the control circuit 11 is equipped with error detection parts that detect errors, such as a protection element 11P and a detection element 11D, etc., (for example, see FIG. 2). The protection element 11P is an error detection part that detects an error in a signal or a voltage that serves as the reason of a malfunction with a high risk level if the power supply device 100 continues to operate. Additionally, the detection element 11D is an error detection part that detects an error in a signal or a voltage that serves as the reason of a malfunction with a lower risk level than those detected by the protection element 11P. In the error detection part, ranking is set according to the risk level of errors of signals or voltages. In the semiconductor device 10 of the disclosure, the protection element 11P can be considered to have a higher risk ranking than the detection element 11D.

For example, if the output voltage VOUT1 output from the output part 20 or the bridge circuit 141 exceeds a fixed range, an erroneous operation of the load (for example, a control device of an engine, a brake, etc.) to which the output voltage VOUT1 is supplied may occur. In such cases, the output voltage VOUT1 may be output to components where an erroneous operation is not permitted for safe vehicle operation, that is, components with C level or D level of ASIL. Therefore, the output voltage VOUT1 of the output part 20 or the bridge circuit 141 is subject to error detection by the protection element 11P.

In the control circuit 11, the feedback signals FB1P, FB1N, FB2P, FB2N, etc., are input to the protection element 11P (see FIG. 2). The protection element 11P detects errors in the feedback signals FB1P, FB1N, FB2P, FB2N, etc., and outputs a first error detection signal SEP to a protection system determination circuit 111 of the control circuit 11, which will be described later. The first error detection signal SEP is, for example, at the low level when the protection element 11P does not detect an error, and at the high level when detecting an error. However, the level of the first error detection signal SEP is not limited to the above.

As the protection element 11P, examples may include over voltage protection (OVP) which detects that a voltage or a signal is greater than a fixed threshold, and under voltage protection (UVP) which detects that a voltage or a signal is smaller than a fixed threshold. Additionally, other than the above, various elements that detect errors in signals or voltages can be widely adopted.

In the semiconductor device 10, the internal voltage VREG is supplied to the control circuit 11. The internal voltage VREG, the feedback signals FB1P, FB1N, FB2P, FB2N, etc., are input to the detection element 11D of the control circuit 11 (see FIG. 2). The detection element 11D detects whether there are errors in the internal voltage VREG, the feedback signals FB1P, FB1N, FB2P, FB2N, etc. The detection element 11D outputs a second error detection signal SED to the detection system determination circuit 112 of the control circuit 11, which will be described later. The second error detection signal SED is, for example, at the low level when the detection element 11D does not detect an error, and at the high level when the detection element 11D detects an error. However, the level of the second error detection signal SED is not limited to the above.

As the detection element 11D, examples may include over voltage detection (OVD) which detects that a voltage or a signal is greater than a fixed threshold, and under voltage detection (UVD) which detects that a voltage or a signal is smaller than a fixed threshold. Additionally, other than the above, various elements that detect errors in signals or voltages can be widely adopted.

Furthermore, if the internal voltage VREG becomes too high, the internal voltage VREG may exceed the withstand voltage of the elements in the semiconductor device 10, and if the internal voltage VREG becomes too low, there is a risk that the operation of the semiconductor device 10 may become unstable. Therefore, error detection may be performed for the internal voltage VREG by both the detection element 11D and the protection element 11P. In other words, the detection element 11D may detect that the internal voltage VREG, which operates within a first range, exceeds the first range, and the protection element 11P may detect that the internal voltage VREG exceeds a second range that is wider than the first range.

In addition, the control circuit 11 is configured to acquire the voltages of both terminals of the capacitor C2 of the rectification smoothing circuit as the feedback signals FB2P, FB2N. The protection element 11P and the detection element 11D of the control circuit 11 execute error detection for the feedback signals FB2P, FB2N, like the case for the feedback signals FB1P, FB1N.

Furthermore, the control circuit 11 includes the protection system determination circuit 111, the detection system determination circuit 112, and an analog built in test (ABIST) diagnostic circuit 113. The first error detection signal SEP output from the protection element 11P is input to the protection system determination circuit 111. The protection system determination circuit 111 determines whether the protection element 11P detects an error based on the first error detection signal SEP.

When determining that the protection element 11P detects an error, the protection system determination circuit 111 notifies the MCU 200 via the interrupt signal INTB that interrupt processing (stop or safe mode operation) is necessary. The interrupt signal INTB is pulled up. For example, the interrupt signal INTB may be a signal that is at a high level when there is no error and becomes a low level when an error is detected.

Additionally, the second error detection signal SED output from the detection element 11D is input to the detection system determination circuit 112. The detection system determination circuit 112 determines whether the detection element 11D detects an error based on the second error detection signal SED. When determining that the detection element 11D detects an error, the detection system determination circuit 112 notifies the MCU 200 that an error is detected via the error signal ERRB. The error signal ERRB is pulled up. For example, the error signal ERRB may be at the high level when there is no error and the low level when an error is detected. The levels of the interrupt signal INTB and the error signal ERRB when an error is detected are not limited to those described above.

In the control circuit 11, to improve the failure detection rate, a self-diagnostic function referred to as ABIST is provided. The self-diagnostic function serves to diagnose whether elements that detect malfunctions, such as the protection element 11P and the detection element 11D, etc., operate accurately.

Here, the ABIST diagnostic circuit 113 of the control circuit 11 will be described. The ABIST diagnostic circuit 113 is configured to be able to output an ABIST enable signal ABEN to the protection element 11P and the detection element 11D. The ABIST enable signal ABEN is at the low level when ABIST is not performed and at the high level when ABIST is performed.

The ABIST diagnostic circuit 113 has a configuration capable of generating pseudo error signals SVP and SVD that include errors that can be detected in advance by the protection element 11P and the detection element 11D of the driver circuits 131, 132, and outputting the pseudo error signals SVP and SVD to the protection element 11P and the detection element 11D respectively.

The first error detection signal SEP output from the protection element 11P and the second error detection signal SED output from the detection element 11D are input to the ABIST diagnostic circuit 113. The ABIST diagnostic circuit 113 diagnoses whether the protection element 11P and the detection element 11D malfunction based on the first error detection signal SEP and the second error detection signal SED.

The ABIST diagnostic circuit 113 notifies the MCU 200 via the data signal SDA that ABIST is performed. Furthermore, the ABIST diagnostic circuit 113 also notifies the MCU 200 of the diagnostic results of the protection element 11P and the detection element obtained through ABIST via the data signal SDA.

The ABIST diagnostic circuit 113 may be connected with signal lines individually transmitting the ABIST enable signal ABEN and the pseudo error signals SVP, SVD to the driver circuit 131 and the driver circuit 132 respectively, and may also be configured to switch to a signal line to output the respective signals to one of the drive circuits 131, 132. Similarly, the signal lines through which the first error detection signal SEP and the second error detection signal SED are input may be configured to be able to receive signals in accordance with the driver circuits 131 and 132 respectively, or may be configured to receive signals by switching between the driver circuits 131 and 132.

It should be noted that while the ABIST diagnostic circuit 113 performs diagnosis on the protection element 11P and the detection element 11D when conducting ABIST, the disclosure is not limited thereto. For example, it may be configured to perform diagnosis of only one of the protection element 11P and the detection element 11D in a single ABIST operation.

In the conventional semiconductor device, ABIST is performed in a period immediately before the system of the power supply device 100 itself is started. In the power supply device 100, there is an increasing demand to perform ABIST (referred to as ABIST on-demand) in a state where the semiconductor device 10 operates continuously, such as a state where the power supply device 100 is operating (hereinafter referred to as an on-demand state).

In the case of performing ABIST on-demand, if the first error detection signal SEP and the second error detection signal SED based on the input of the pseudo error signals SVP and SVD are input to the protection system determination circuit 111 and the detection system determination circuit 112, incorrect interrupt signal INTB and error signal ERRB may be output to the MCU 200. Therefore, in the control circuit 11, a mask circuit 114 is provided, so that the first error detection signal SEP is not input to the protection system determination circuit 111 and the second error detection signal SED is not input to the detection system determination circuit 112 when ABIST is performed.

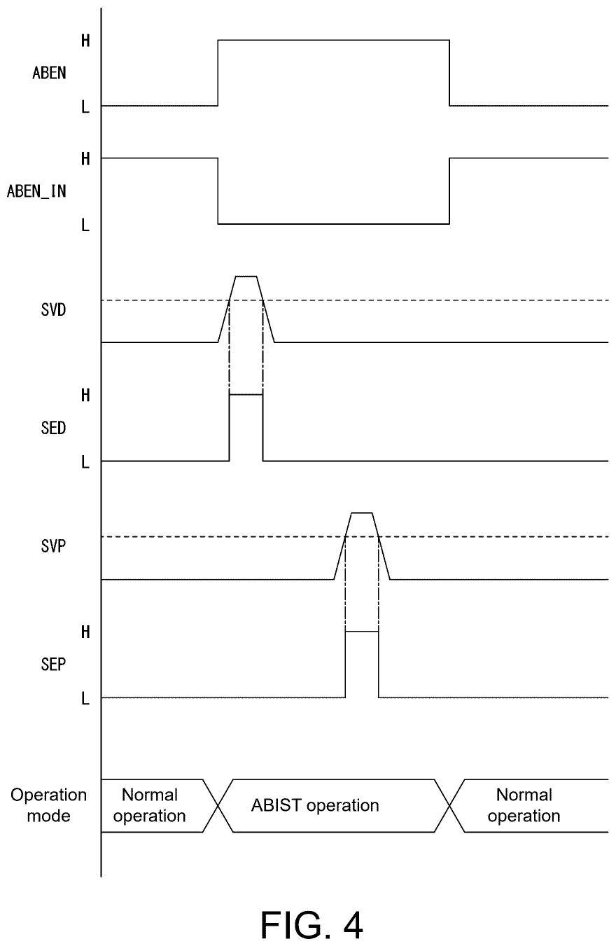

As shown in FIG. 2, the mask circuit 114 has a circuit configuration having AND circuits 115 and 116. An inverted signal ABEN_INV (see FIG. 4 to FIG. 7 described later) obtained by inverting the ABIST enable signal ABEN is input to one input terminal of the AND circuit 115. The inverted signal ABEN_INV of the ABIST enable signal ABEN is at the low level when the ABIST enable signal ABEN is at the high level, and at the high level when the ABIST enable signal ABEN is at the low level. The first error detection signal SEP is input to the other input terminal of the AND circuit 115. The logical OR of the inverted signal ABEN_INV of the ABIST enable signal ABEN and the first error detection signal SEP is output to the AND circuit 115. The output of the AND circuit 115 is input to the protection system determination circuit 111.

Additionally, the inverted signal ABEN_INV of the ABIST enable signal ABEN is input to one input terminal of the AND circuit 116. The second error detection signal SED is input to the other input terminal of the AND circuit 116. The logical OR of the inverted signal of the ABIST enable signal ABEN and the first error detection signal SEP is output to the AND circuit 116. The output of the AND circuit 115 is input to the detection system determination circuit 112.

In the case of performing ABIST, the high level of the ABIST enable signal ABEN is output from the ABIST diagnostic circuit 113. The inverted signal ABEN_INV of the ABIST enable signal ABEN becomes the low level, and the outputs of the AND circuit 115 and the AND circuit 116 both become the low level. Therefore, when performing ABIST, low level signals are input to the protection system determination circuit 111 and the detection system determination circuit 112. In other words, the first error detection signal SEP and the second error detection signal SED are in a masked state with respect to the protection system determination circuit 111 and the detection system determination circuit 112.

On the other hand, in the case of not performing ABIST, the high level of the inverted signal ABEN_INV of the ABIST enable signal ABEN is input to one input terminal of each of the AND circuit 115 and the AND circuit 116. Therefore, the AND circuit 115 outputs an output signal with the same logic value as the first error detection signal SEP. Also, the AND circuit 116 outputs an output signal with the same logic value as the second error detection signal SED.

The power supply device 100 includes the configuration.

### ABIST On-Demand

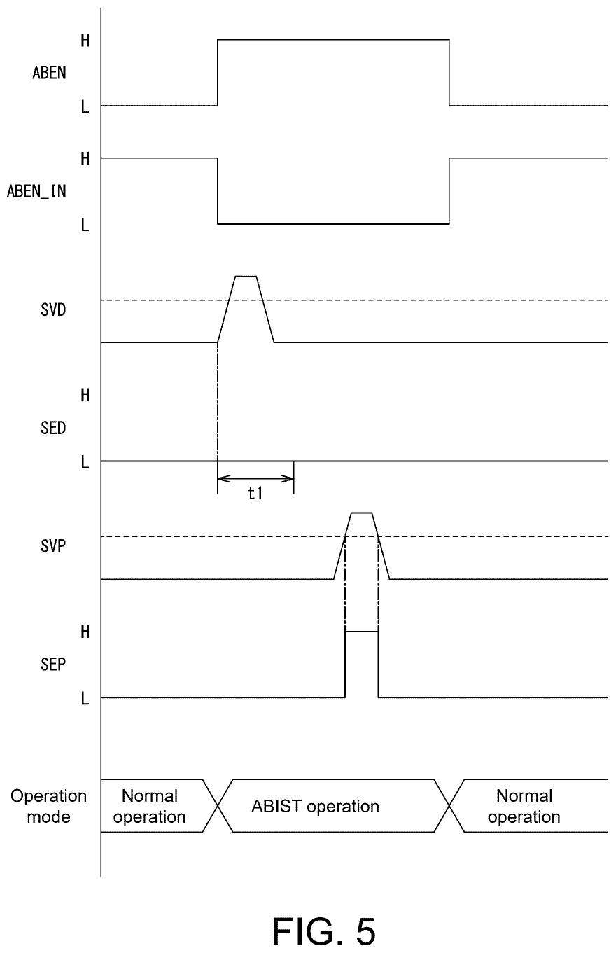

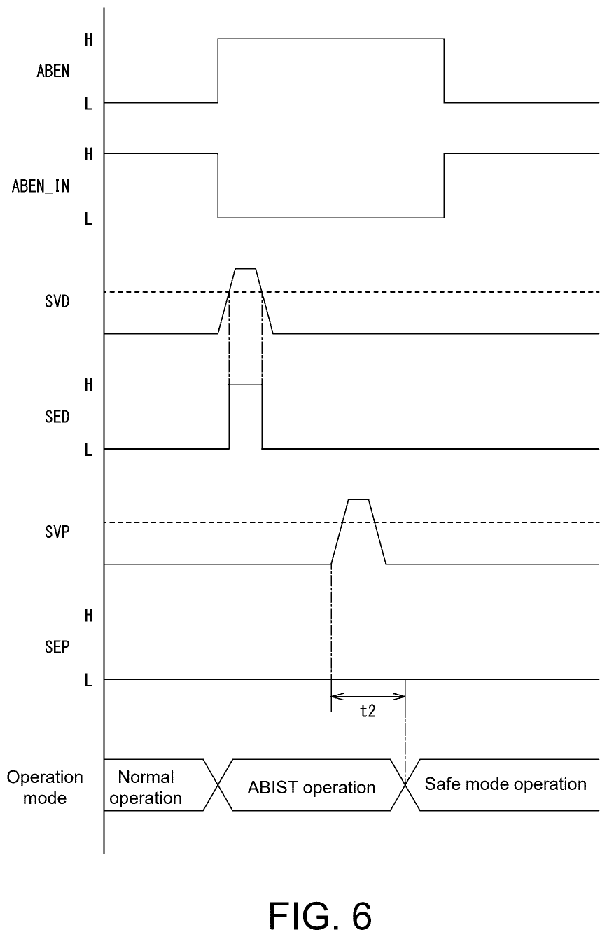

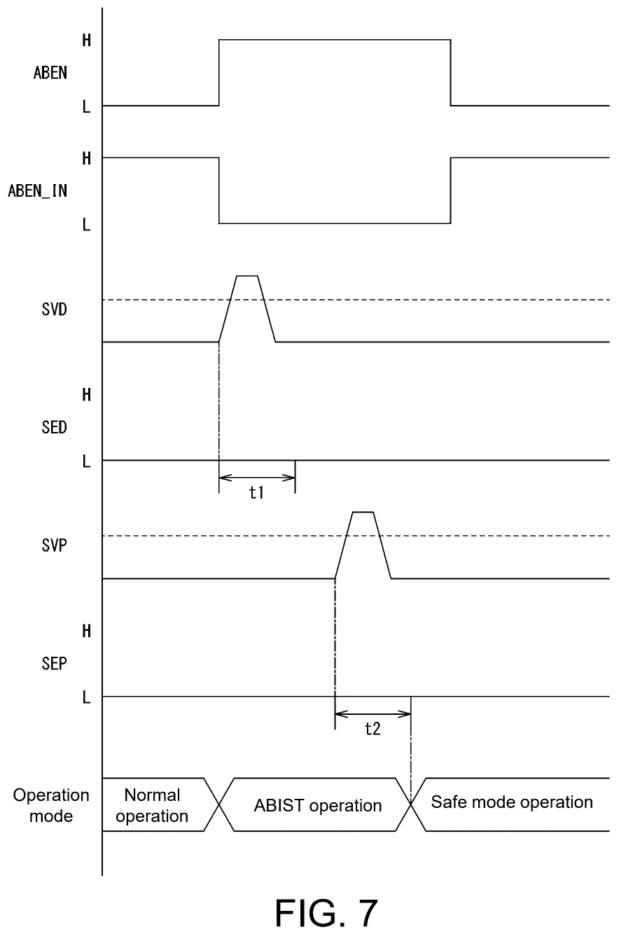

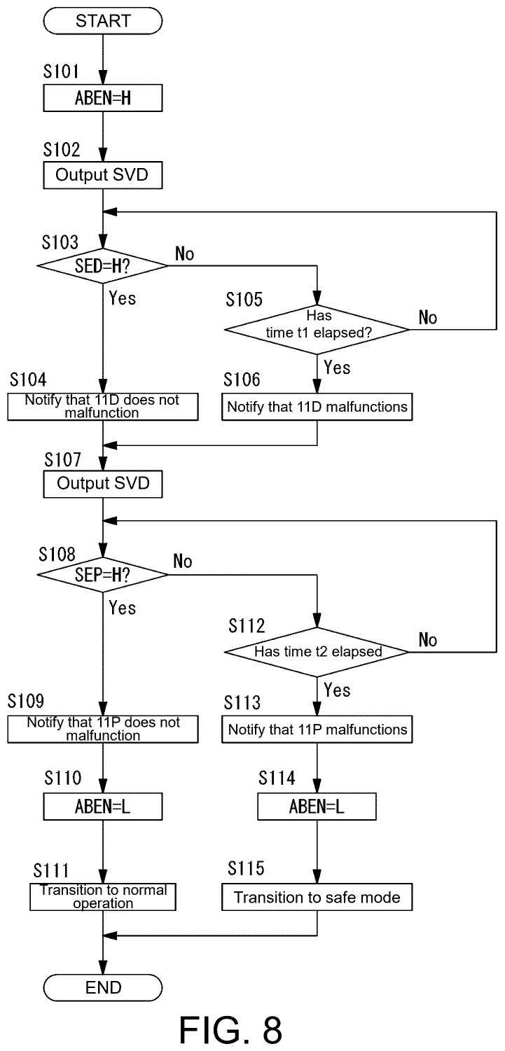

Next, the operation in the case of performing ABIST on-demand in the power supply device 100 will be described with reference to the drawings. FIG. 4 is a diagram showing the state of each signal when there is no malfunctioning in the protection element 11P and the detection element 11D in ABIST on-demand. FIG. 5 is a diagram showing the state of each signal when the detection element 11D malfunctions. FIG. 6 is a diagram showing the state of each signal when the detection element 11D malfunctions. FIG. 7 is a diagram showing the state of each signal when the detection element 11D and protection element 11P malfunction. FIG. 8 is a flowchart showing processes of ABIST on-demand.

In the semiconductor device 10, it is possible to execute ABIST on-demand, which performs ABIST in a state where the power supply device 100 outputs an output voltage. Here, the operation mode of the semiconductor device 10 is defined as follows. The situation where the power supply device 100 normally outputs an output voltage is defined as normal operation. The state where the power supply device 100 performs ABIST is defined as ABIST operation. The operation mode where the power supply device 100 switches to a safe side, such as stopping the power supply device 100 or reducing output based on ABIST, is defined as safe mode operation (see FIG. 4 to FIG. 7).

In ABIST on-demand, even when performing ABIST operation, the power supply device 100 operates to output the same output voltage and output current as in normal operation.

As shown in FIG. 8, when switching from normal operation to ABIST operation, the ABIST enable signal ABEN output from the ABIST diagnostic circuit 113 switches to the high level (Step S101). The ABIST enable signal ABEN is maintained at the high level during the ABIST operation period. The ABIST enable signal ABEN is input to the detection element 11D and the protection element 11P. During ABIST operation, the voltage, signals, etc., that are input to the detection element 11D and the protection element 11P during normal operation are configured to be masked. In other words, during ABIST operation, the error detection performed by the detection element 11D and the protection element 11P in normal operation is not performed.

Also, the inverted signal ABEN_INV of the ABIST enable signal ABEN is input to the AND circuit 115 and the AND circuit 116 of the mask circuit 114. That is, ABEN_INV of the low-level is input to the AND circuit 115 and the AND circuit 116. Therefore, the outputs of the AND circuit 115 and the AND circuit 116 become the low level regardless of the levels of the first error detection signal SEP and the second error detection signal SED (see FIG. 4 to FIG. 7). In other words, the input of the first error detection signal SEP from the protection element 11P to the protection system determination circuit 111 is masked. Similarly, the input of the second error detection signal SED from the detection element 11D to the detection system determination circuit 112 is masked.

In such state, the ABIST diagnostic circuit 113 outputs the pseudo error signal SVD to the detection element 11D (Step S102; see FIG. 4 to FIG. 7). The detection element 11D outputs the second error detection signal SED, and the second error detection signal SED is input to the ABIST diagnostic circuit 113 (see FIG. 2). The ABIST diagnostic circuit 113 diagnoses whether the detection element 11D malfunctions based on the level of the second error detection signal SED. When the pseudo error signal SVD is input, the detection element 11D outputs the high level of the second error detection signal SED. Therefore, the ABIST diagnostic circuit 113 confirms whether the second error detection signal SED switches to the high level (Step S103).

When confirming that the second error detection signal SED switches to the high level (when YES in Step S103), the ABIST diagnostic circuit 113 determines that there is no malfunction in the detection element 11D and notifies the MCU 200 (Step S104: see FIG. 4).

Also, when it is not confirmed that the second error detection signal SED becomes the high level (when NO in Step S103), the ABIST diagnostic circuit 113 cannot determine whether the detection element 11D malfunctions or there is a delay time until the second error detection signal SED switches to the high level. Therefore, when it is not confirmed that the second error detection signal SED becomes the high level (when NO in Step S103), the ABIST diagnostic circuit 113 confirms whether a fixed time t1 has elapsed since the pseudo error signal SVD is output (Step S105: see FIG. 5).

When the fixed time t1 has not elapsed since the pseudo error signal SVD is output (when NO in Step S105), the process returns to Step S103 and continues. Also, when the fixed time t1 has elapsed since the pseudo error signal SVD is output (when YES in Step S105), the ABIST diagnostic circuit 113 determines that the detection element 11D malfunctions and notifies the MCU 200 (Step S106).

In this way, the ABIST diagnostic circuit 113 performs malfunctioning diagnosis on the detection element 11D during ABIST and transmits the results. As described above, the detection element 11D is an element for detecting an error in signals or voltages supplied to components with a low risk level. Therefore, in the case of receiving a notification that the detection element 11D malfunctions, the MCU 200 performs an operation such as transmitting the notification externally.

Also, after notifying that there is no malfunction in the detection element 11D in Step S104, or after notifying that the detection element 11D malfunctions in Step S106, the process transitions to ABIST of the protection element 11P. Specifically, the ABIST diagnostic circuit 113 outputs the pseudo error signal SVP to the protection element 11P (Step S107).

The ABIST diagnostic circuit 113 diagnoses whether the protection element 11P malfunctions based on the level of the first error detection signal SEP. When the pseudo error signal SVP is input, the protection element 11D outputs the high level of the first error detection signal SEP. Therefore, the ABIST diagnostic circuit 113 confirms whether the first error detection signal SEP switches to the high level (Step S108).

When confirming that the first error detection signal SEP switches to the high level (when YES in Step S108), the ABIST diagnostic circuit 113 determines that there is no malfunction in the protection element 11P and notifies the MCU 200 (Step S109). Then, the ABIST diagnostic circuit 113 switches the ABIST enable signal ABEN to the low level (Step S110). As a result, the operation mode switches from ABIST operation to normal operation (Step S111: see FIG. 4 and FIG. 5).

Also, when it is not confirmed that the first error detection signal SEP becomes the high level (when NO in Step S108), the ABIST diagnostic circuit 113 cannot determine whether the detection element 11D malfunctions or there is a delay time until the first error detection signal SEP switches to the high level. Therefore, when it is not confirmed that the first error detection signal SEP becomes the high level (when NO in Step S108), the ABIST diagnostic circuit 113 confirms whether a fixed time t2 has elapsed since the pseudo error signal SVP is output (Step S112).

When the fixed time t2 has not elapsed since the pseudo error signal SVP is output (when NO in Step S112), the process returns to Step S108 and continues. Also, when the fixed time t2 has elapsed since the pseudo error signal SVP is output (when YES in Step S112), the ABIST diagnostic circuit 113 determines that the detection element 11P malfunctions and notifies the MCU 200 (Step S113: FIG. 6, FIG. 7). Then, the ABIST diagnostic circuit 113 switches the ABIST enable signal ABEN to the low level (Step S114).

The MCU 200 changes the standby signal STBY, the enable signal EN, and the data signal SDA output to the control circuit 11 of the semiconductor device 10, and switches the operation mode of the power supply device 100 from ABIST operation to safe mode operation (Step S111: see FIG. 6 and FIG. 7).

The ABIST diagnostic circuit 113 performs malfunctioning diagnosis on the protection element 11P during ABIST and transmits the results. As described above, the protection element 11P is an element for detecting an error in signals or voltages supplied to components with a high risk level. Therefore, when receiving the notification that the protection element 11P malfunctions, the MCU 200 operates to reduce the risk level of the vehicle by transitioning to safe mode operation, which suppresses or stops the output voltage and the output current output from the power supply device 100.

According to the semiconductor device 10, ABIST can be executed during operation as ABIST on-demand, and the fault detection rate by the protection element 11P and the detection element 11D can be compensated.

When performing ABIST at system startup, it is also possible to diagnose the detection functions of the protection system determination circuit 111 and the detection system determination circuit 112 by not outputting the ABIST enable signal ABEN, while inputting the first error detection signal SEP to the protection system determination circuit 111 and inputting the second error detection signal SED to the detection system determination circuit 112 during ABIST. Also, in the example described above, the diagnosis of the protection element 11P is performed after the diagnosis of the detection element 11D, but the order may be reversed. Alternatively, only one of the diagnoses may be performed in a single ABIST.

### MODIFIED EXAMPLE

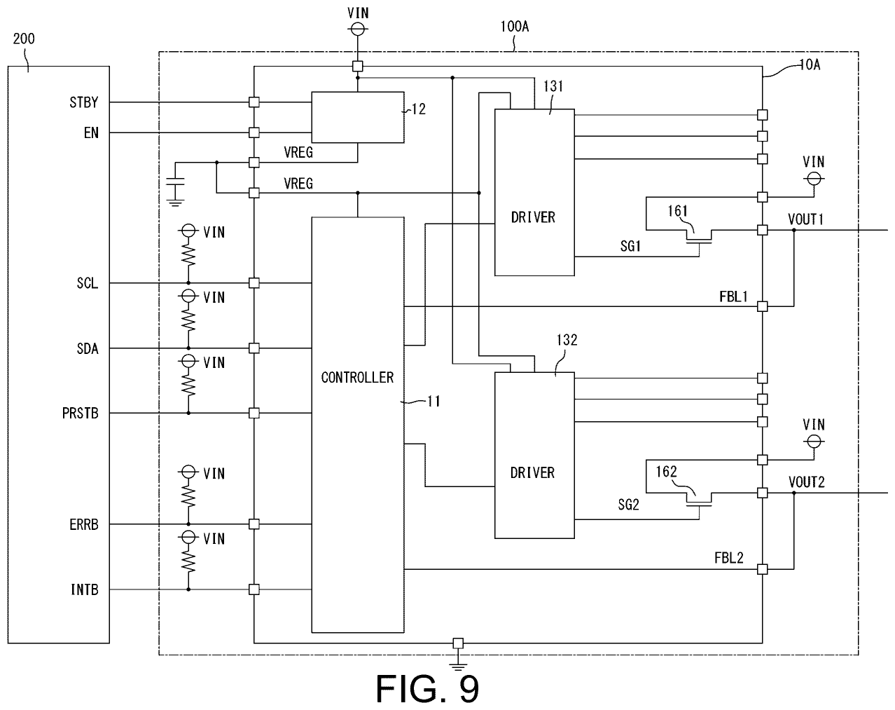

A power supply device 100A of the modified example will be described with reference to the drawings. FIG. 9 is a diagram showing the configuration of the power supply device 100A according to the modified example. The power supply device 100A shown in FIG. 9 differs in that a semiconductor device 10A is different from the semiconductor device 10. More specifically, the semiconductor device 10A differs from the semiconductor device 10 in that the semiconductor device 10A includes NMOS transistors 161 and 162 in place of the bridge circuits 141 and 142 provided in the semiconductor device 10. Other parts of the semiconductor device 10A have substantially the same configurations as the semiconductor device 10, and the same reference numerals are assigned to substantially the same parts, with detailed explanations omitted.

As shown in FIG. 9, the semiconductor device 10A includes the NMOS transistors 161 and 162. The drain of the NMOS transistor 161 is connected to the application terminal of the input voltage VIN. The source voltage of the NMOS transistor 161 is the output voltage VOUT1. Also, a gate signal SG1 from the driver circuit 131 is input to the gate of the NMOS transistor 161. In the NMOS transistor 161, the ON resistance is controlled by the gate signal SG1. Then, the output voltage VOUT1, which is the input voltage VIN reduced by the voltage drop due to the ON resistance of the NMOS transistor 161, is output externally.

A feedback voltage FBL1 corresponding to the output voltage VOUT1 is input to the control circuit 11. The control circuit 11 determines the voltage value of the output voltage VOUT1 from the feedback voltage FBL1. Then, the control circuit 11 controls the driver circuit 131 so that the output voltage value determined from the feedback voltage FBL1 becomes a predetermined voltage value.

Also, the NMOS transistor 162 is connected to the driver circuit 132. That is, the ON resistance is adjusted according to a gate signal SG2 supplied from the driver circuit 132, and the output voltage VOUT2, which is the input voltage VIN reduced by the voltage drop of the ON resistance, is output externally.

A feedback voltage FBL2 corresponding to the output voltage VOUT2 is input to the control circuit 11. The control circuit 11 determines the voltage value of the output voltage VOUT2 from the feedback voltage FBL2. Then, the control circuit 11 controls the driver circuit 132 so that the output voltage value determined from the feedback voltage FBL2 becomes a predetermined voltage value.

The power supply device 100A is a power supply device that includes a so-called linear regulator that generates the output voltages VOUT1 and VOUT2 by utilizing the voltage drops due to the ON resistances of the NMOS transistors 161 and 162. With the configuration, the power supply device 100A can perform ABIST on-demand in the same way as the power supply device 100.

In the modified example, the output stages of two channels are configured as linear regulators, but the disclosure is not limited thereto, and the other channel may be a switching regulator with a bridge circuit. Also, the output part 20 including a bridge circuit may be connected to the configuration of the semiconductor device 10A of the modified example, and the output part 20 may be operated. In this case, the linear regulator of the channel to which the output part 20 is connected may be stopped.

### Utilization

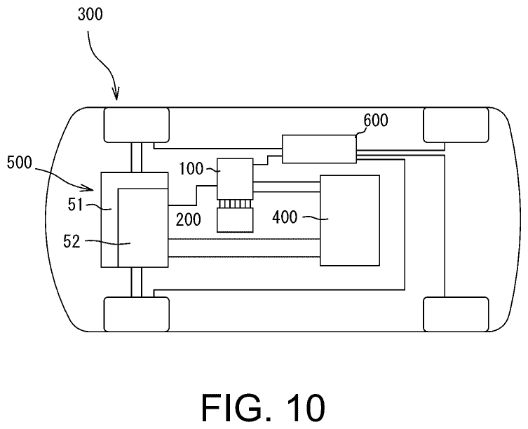

FIG. 10 is a diagram showing the configuration of an example of a vehicle 300 including the power supply device 100. The vehicle 300 includes the power supply device 100, the MCU 200, a battery 400, a motor device 500, and an automatic brake system 600. The motor device 500 includes a motor 51 and a motor drive device 52. The motor drive device 52 is configured to adjust the voltage and the current supplied from the battery 400 and supply the adjusted voltage and current to the motor 51. The voltage and the current for operating the motor drive device 52 are supplied from the power supply device 100.

The automatic brake system 600 is a device that controls a brake (not shown) provided in the vehicle 300, and performs operations such as activating a predetermined when wheels (not shown) are spinning, and automatically activating the brake when the vehicle 300 abnormally approaches an obstacle. The voltage and the current are supplied from the power supply device 100 to the automatic brake system 600, which operates based on the voltage and the current.

The power supply device 100 is configured to output an output voltage with an appropriate voltage value and an output current with an appropriate current value to each of the motor device 500 and the automatic brake system 600, based on the voltage supplied from the battery 400. For example, the output voltage VOUT1 and output current IOUT1 from the output part 20 shown in FIG. 1 are supplied to the motor device 500, and the output voltage VOUT2 and output current IOUT2 from the bridge circuit 142 are supplied to the automatic brake system 600.

In the vehicle 300, the motor device 500 is an element belonging to ASIL_C, and the automatic brake system 600 is an element belonging to ASIL_D. In the power supply device 100, by configuring the protection element 11P to detect errors in the voltages supplied to such components, when errors occur in the voltages supplied to such components, the operation mode that supplies a voltage to safely stop the vehicle 300 can be set as the safe mode operation. By performing ABIST on-demand, the probability of detecting errors in the supply voltage is increased, the vehicle 300 can be suppressed from entering a critical situation due to the errors in the supply voltage.

It should be noted that in the description, while the semiconductor device 10 is described by using an automotive IC as an example, the disclosure is not limited thereto. For example, it can be widely adopted in industrial equipment, ships, aircrafts, etc., devices and equipment that require highly accurate detection of signal or voltage errors.

### Others

The above embodiments should be considered as exemplary in all aspects and not restrictive. Furthermore, the technical scope of the disclosure is indicated not by the description of the above embodiment but by the claims. Moreover, it should be understood that all modifications belonging to equivalent meaning and range of the claims are included.

### Appendix

A semiconductor device (1) as described above includes: an analog circuit (131, 132); a control circuit (11), configured to control the analog circuit (131, 132); an error detection part (11P, 11D), disposed in the control circuit (11) and configured to detect an error and output an error detection signal (SEP, SED); a determination circuit (111, 112), configured to determine whether the error occurs based on the error detection signal (SEP, SED); and a diagnostic circuit (113), configured to diagnose whether the error detection part (11P, 11D) is good based on the error detection signal (SEP, SED). The diagnostic circuit (113) is able to perform in-operation diagnosis (ABIST on-demand) in which the error detection part (11P, 11D) is operated, in a state in which the analog circuit (131, 132) operates. The semiconductor device is configured (first configuration) to have a mask circuit (114) that masks inputting of the error detection signal (SEP, SED) to the determination circuit (111, 112) when the in-operation diagnosis (ABIST on-demand) is performed.

In the semiconductor device (10) of the first configuration, it may also be configured (second configuration) that the control circuit (11) is configured to output externally a notification signal (SDA) including diagnosis results according to the diagnostic circuit (11).

In the semiconductor device (10) of the second configuration, it may also be configured (third configuration) that the error detection part (11P, 11D) is configured as being ranked according to a risk level of the error of the signal or the voltage, and the control circuit (11) is configured to output externally the notification signal (SDA) that differs depending on a ranking of the error detection part (11P, 11D).

In the semiconductor device (10) of any one of the first to third configurations, it may also be configured (fourth configuration) that at least a portion (11P) of the error detection part is configured to detect an error of an output voltage (VOUT1, VOUT2) of the analog circuit (131, 132) and output, as the error detection signal (SEP), a detection result.

In the semiconductor device (10) of any one of the first to fourth configurations, it may also be configured (fifth configuration) that at least a portion (11D) of the error detection part is configured to detect an error of an internal voltage (VREG) supplied to the analog circuit (131, 132) and outputs, as the error detection signal (SDA), a detection result.

A power supply device (100) as described above may be configured (sixth configuration) to include: the semiconductor device (10) as claimed in any one of the first to fifth configurations; and a switching output part (141, 142, 20), operated according to the analog circuit (131, 132).

A power supply device (100A) as described above may be configured (seventh configuration) to include: the semiconductor device (100A) as claimed in any one of the first to fifth configurations; and a linear output part (151, 152), operated according to the analog circuit (131, 132).

A vehicle (300) as described above may be configured (eighth configuration) to have the power supply device (100, 100A) according to the sixth or seventh configuration.

What is claimed is:

1. A diagnostic circuit, comprising:
an analog circuit;
a control circuit, configured to control the analog circuit;
an error detection part, disposed in the control circuit and configured to detect an error of a signal or a voltage and output an error detection signal;
a determination circuit, configured to determine whether the error occurs based on the error detection signal; and
a diagnostic circuit, configured to diagnose whether the error detection part is good based on the error detection signal,
wherein the diagnostic circuit is able to perform in-operation diagnosis in which the error detection part is operated, in a state in which the analog circuit operates, and
the semiconductor device is configured to have a mask circuit that masks inputting of the error detection signal to the determination circuit when the in-operation diagnosis is performed.

2. The semiconductor device as claimed in claim 1, wherein the control circuit is configured to output externally a notification signal comprising diagnosis results according to the diagnostic circuit.

3. The semiconductor device as claimed in claim 2, wherein the error detection part is configured as being ranked according to a risk level of the error of the signal or the voltage, and
the control circuit is configured to output externally the notification signal that differs depending on a ranking of the error detection part.

4. The semiconductor device as claimed in claim 3, wherein at least a portion of the error detection part is configured to detect an error of an output voltage of the analog circuit and output, as the error detection signal, a detection result.

5. The semiconductor device as claimed in claim 3, wherein at least a portion of the error detection part is configured to detect an error of an internal voltage supplied to the analog circuit and outputs, as the error detection signal, a detection result.

6. A power supply device, comprising: the semiconductor device as claimed in claim 1; and
a switching output part, operated according to the analog circuit.

7. A power supply device, comprising: the semiconductor device as claimed in claim 1; and
a linear output part, operated according to the analog circuit.

8. A vehicle, configured to have the power supply device as claimed in claim 6.

9. A vehicle, configured to have the power supply device as claimed in claim 7.
